(19) United States
(12) Patent Application Publication
(10) Pub. No.: US 2026/0331196 A1
(43) Pub. Date: Oct. 22, 2026

(54) BLOCK FAMILY CALIBRATION AND COMBINATION OPERATIONS

(71) Applicant: MICRON TECHNOLOGY, INC., Boise, ID (US)

(72) Inventors: Chao-Han Cheng, San Jose, CA (US); Chia-Wei Chang, Hsinchu City (TW); Jen Hung Liao, Zhubei City (TW); Chung-An Hsu, Zhubei City (TW)

(21) Appl. No.: 19/184,404

(22) Filed: Apr. 21, 2025

(51) Int. Cl. G11C 29/02; G11C 16/28; G11C 29/52

(52) U.S. Cl. CPC G11C 29/028; G11C 16/28; G11C 29/52; G11C 2207/2254

(57) ABSTRACT

A processing device selects a voltage offset bin. The processing device selects first and second block families associated with the bin. The processing device selects a first subset of pages from a first subset of blocks corresponding to the first block family and a second subset of pages from a second subset of blocks corresponding to the second block family. The processing device performs a read level calibration scan on the first and second subsets of pages. The processing device calculates a first offset metric corresponding to the first block family and a second offset metric corresponding to the second block family. The processing device determines whether the first and second block families satisfy a combination threshold criterion. Responsive to determining that the first and second block families satisfy the combination threshold criterion, the processing device combines the first and second block families to create a combination block family.

### TECHNICAL FIELD

Embodiments of the disclosure relate generally to memory sub-systems, and more specifically, relate to performing block family calibration and combination operations.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2 schematically illustrates the temporal voltage shift caused by the slow charge loss exhibited by triple-level memory cells, in accordance with some embodiments of the present disclosure.

FIG. 3 depicts an example graph illustrating the dependency of the threshold voltage offset on the time after program (i.e., the period of time elapsed since the block had been programmed, in accordance with some embodiments of the present disclosure.

FIG. 4 schematically illustrates a set of predefined threshold voltage offset bins, in accordance with embodiments of the present disclosure.

FIG. 5 schematically illustrates selecting block families associated with a voltage offset bin for calibration and combination operations, in accordance with embodiments of the present disclosure.

FIG. 6 illustrates a block family table maintained by a memory sub-system controller, in accordance with embodiments of the present disclosure.

FIG. 7A is a flow diagram of an example method for performing block family calibration and combination operations in accordance with some embodiments of the present disclosure.

FIG. 7B is a flow diagram of an example method for performing block family calibration and combination operations in accordance with some embodiments of the present disclosure.

FIG. 8 is a block diagram of an example computer system in which embodiments of the present disclosure may operate.

### DETAILED DESCRIPTION

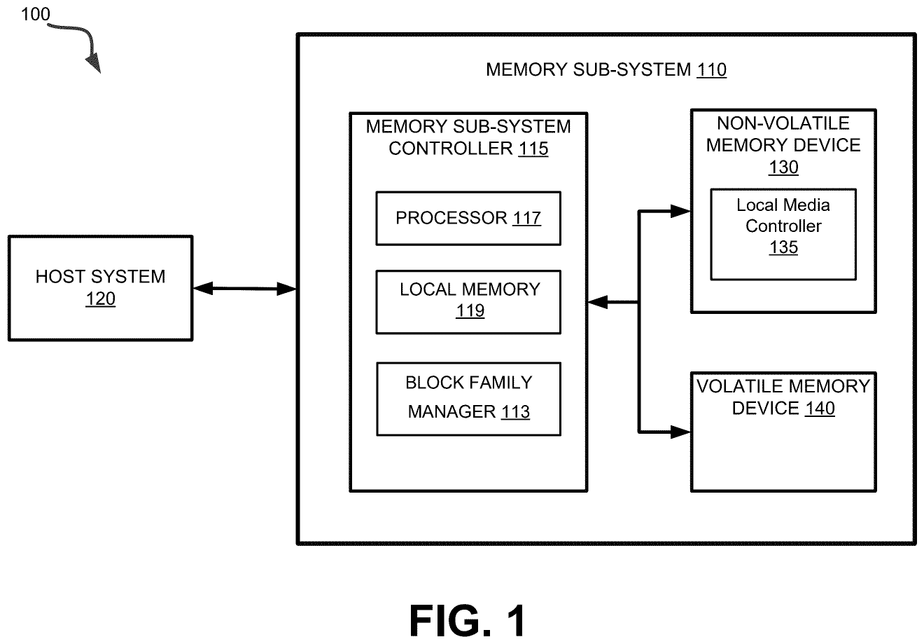

Aspects of the present disclosure are directed to performing block family calibration and combination operations. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a not-and (NAND) memory device. Other examples of non-volatile memory devices are described below in conjunction with FIG. 1. A non-volatile memory device is a package of one or more dies. Each die can includes of one or more planes. For some types of non-volatile memory devices (e.g., NAND devices), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or a three-dimensional grid. The memory cells can be formed onto a silicon wafer in an array of columns and rows. A bitline can refer to one or more conductive lines coupled to a column of associated memory cells in a memory device. A wordline can refer to one or more conductive lines coupled to a row of associated memory cells in a memory device that are used with one or more bitlines to generate the address of each of the memory cells. The intersection of a bitline and a wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include multiple access line driver circuits and power circuits that can be shared by the planes of the memory device to facilitate concurrent access of pages of two or more memory planes, including different page types. For ease of description, these circuits can be generally referred to as independent plane driver circuits. Depending on the storage architecture employed, data can be stored across the memory planes (i.e., in stripes). Accordingly, one request to read a segment of data (e.g., corresponding to one or more data addresses), can result in read operations performed on two or more of the memory planes of the memory device. Each memory block can include a number of sub-blocks, wherein each sub-block is defined by an associated pillar (e.g., a vertical conductive trace) extending from a shared bitline.

A memory device includes multiple memory cells capable of storing, depending on the memory cell type, one or more bits of information. A memory cell can be programmed (written to) by applying a certain voltage to the memory cell, which results in an electric charge being held by the memory cell known as the “threshold voltage” and denoted as Vt.

A memory device can have distributions that are narrow compared with the working range of control voltages tolerated by the cells of the device. Accordingly, multiple distributions (with “valleys” between distributions) can be fit into the working voltage window allowing storing and reliably detecting multiple bits per cell such as 2³=8 distributions (7 valleys) for TLC, 2²=4 distributions (3 valleys) for MLC etc. The distributions are interspersed with voltage intervals (“valley margins”) between distributions where none (or very few) of the memory cells of the device have their threshold voltages. These valley margins can effectively differentiate various charge states. The logical state of the cell can be ascertained by applying specific read voltages to each valley during a read operation. This effectively allows a single memory cell to store multiple bits of information: a memory cell operated with 2^{N} distributions (which are also called levels) is capable of storing N bits of information. During the read operation, 2^{N}−1 read voltages are applied to distinguish 2^{N} distributions. Specifically, the read operation can be performed by comparing the measured threshold voltage V_{T} exhibited by the memory cell to one or more reference voltage levels corresponding to known valleys (e.g., centers of the valleys) of the memory device.

Due to a phenomenon known as slow charge loss (SCL), the threshold voltage V_{T} of a memory cell can change with time as the electric charge of the cell is diminishing. This process is sometimes referred to as “temporal voltage shift” (TVS). “Storage charge loss” and “system charge loss” naming is also used for SCL. Since typical cells store negatively charged particles (electrons), the loss of electrons causes the voltage thresholds to shift along the voltage axis towards lower voltage thresholds V_{T}. The threshold voltages can change rapidly at first (immediately after the memory cell is programmed) while slowing down at larger times in an approximately log-linear or power-law fashion (ΔV_{T}(t)=−C*t^{b}) with respect to the time t elapsed since the cell programming event. In some embodiments of the present disclosure, TVS can be mitigated by keeping track of the time elapsed since the programming event as well as of the environmental conditions of a particular memory partition (block, plane, etc.) such as temperature and associating a voltage offset ΔV_{T} per valley to be used during read operations, where the standard “base read level” threshold voltage V_{T} (displayed by the cell immediately after programing) is modified by the voltage offset: V_{T}→V_{T}+ΔV_{T} where ΔVT is negative due to charge loss. Whereas TVS is a continuous process and compensating for ΔV_{T}(t) can be a continuous function of time, adequate accuracy of offsets can be achieved in some embodiments with a discrete number of offset state information bins (hereafter referred to as “bins”). Blocks can be associated with a bin using metadata (e.g., programmed within a specified time window and under similar environmental (e.g., temperature) conditions). Since the time elapsed since programming and temperature conditions are among the main factors affecting the amount of TVS, blocks associated with the same bin can be presumed to exhibit similar distributions of threshold voltages of their memory cells, and thus would require the same voltage offsets to be applied to the base read levels for read operations.

A Block Family Error Avoidance (BFEA) mechanism allows tracking Slow Charge Loss (SCL)—also known as temporal voltage shift (TVS)—and applying the appropriate voltage offsets during read operations to maintain a low Bit Error Rate (BER). Since the TVS is a function of both the elapsed time since programming and environmental factors like temperature, memory systems can use a binning strategy to group blocks with similar charge loss profiles. Blocks programmed under similar conditions are grouped into discrete bins, and each bin is associated with a set of voltage offsets to be applied during read operations. The memory sub-system controller periodically calibrates the device, updating these auxiliary read metadata (ARM) tables to reflect the current state of each block and ensure the appropriate offset is used.

Within the BFEA scheme, a periodic scan—which can be based on the shift of the highest logical voltage level (e.g., voltage level 7)—can determine the current bin for each block, with the scanning cadence set according to both the bin value and the operating temperature. As time passes, the bin value tends to saturate, meaning that further SCL may not be accurately reflected if the block isn't rescanned. In use cases such as in automotive applications, the SSD is powered off for extended periods (for example, 7-8 hours when the vehicle is parked). During these long power-off periods, the bin information determined before shutdown may no longer be optimal when the device is powered back on, because the cells' threshold voltages have continued to shift.

This issue can be exacerbated by the fact that blocks with lower bin values, which have experienced less charge loss, are scanned more frequently and are thus more likely to be updated during typical vehicle usage sessions. In contrast, blocks in higher bins—requiring longer scan intervals—may miss their scheduled updates if the SSD isn't powered on long enough. Consequently, these blocks remain exposed to further SCL without the benefit of timely recalibration.

Adding to the complexity, the memory controller has a finite number of Block Families (BFs) available for managing these bin-specific offsets. Under normal conditions, blocks with adjacent shifts (i.e., similar SCL characteristics) are combined during the scan process, freeing up resources. Furthermore, employing a larger number of BFs not only consumes more memory but also necessitates increased background scanning activity to perform the scan, which can impact host latency. If blocks in higher bins do not get updated due to insufficient power-on time, forced combining may occur. This exception handling forces the merge of BFs regardless of their SCL profile differences, potentially leading to suboptimal offset adjustments and a degraded trigger rate for error correction.

Aspects of the present disclosure address the above and other deficiencies by having a memory sub-system that can perform block family calibration and combination operations, independent of the block family calibration scan cadence. Specifically, the memory sub-system selects a number of block families associated with a voltage offset bin and a number of pages corresponding to each block family. In some embodiments, the system performs a dummy read operation on all the blocks associated with the voltage offset bin to prepare the blocks for a read level calibration scan. The system performs a read level calibration scan on the selected pages of each selected block family. In some embodiments, the read level calibration scan used is a vectorized read level calibration scan. For each of the selected block families, the system calculates an offset metric. In some embodiments, the offset metric is a statistical aggregate (e.g., the median) of a set of offset values associated with the selected number of pages associated with a block family. The system determines, based on the offset metric for each selected block family, whether the selected block families satisfy a combination threshold criterion. In some embodiments, the combination threshold criterion specifies the maximum difference between the offset metrics associated with the selected block families. If the combination threshold is satisfied, the system combines the selected block families into one block family. If the combination threshold criterion is not satisfied, the system can select other block families to measure against the combination threshold criterion. In some embodiments, the other block families include a number of the previously selected block families. In some embodiments, upon combining the selected block families, if there are additional block families that have been selected in the bin, the system can select a next unselected pair of block families to perform the above operations with. In some embodiments, if there are not additional block families that have been selected in the bin, but if there are additional bins that have not had block families selected, the system can perform the above operations on block families within a next bin.

Advantages of the present disclosure include, but are not limited to improved reliability and improved performance. By decoupling block family calibration and combination operations from the calibration scan cadence, the system can prevent bin stall from occurring and also prevent the need for force combination operations, thereby significantly improving reliability. This allows the system to provide a consistent, updated bitmap for subsequent media algorithms Furthermore, in embodiments where the dummy operation is performed with respect to all of the blocks associated with the selected bin, the system uniformly prepares each block for the subsequent read level calibration scan, eliminating the need for periodic dummy read operations during the scan and reducing system latency.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a not-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

The memory sub-system 110 includes a block family manager component 113 that can perform block family calibration and combination operations, independent of the block family calibration scan cadence. In some embodiments, the memory sub-system controller 115 includes at least a portion of the block family manager component 113. In some embodiments, the block family manager component 113 is part of the host system 120, an application, or an operating system. In other embodiments, local media controller 135 includes at least a portion of block family manager component 113 and is configured to perform the functionality described herein.

The block family manager component 113 can perform block family calibration and combination operations, independent of a block family calibration scan cadence. Specifically, the memory sub-system selects a number of block families associated with a voltage offset bin and a predefined number of pages corresponding to each block family. In some embodiments, the system performs a dummy read operation on all the blocks associated with the voltage offset bin to prepare the blocks for a read level calibration scan. The system performs a read level calibration scan on the selected pages of each selected block family. In some embodiments, the read level calibration scan used is a vectorized read level calibration scan. For each of the selected block families, the system calculates an offset metric. In some embodiments, the offset metric is a statistical aggregate (e.g., median) of the offset values associated with the selected pages of the block family. The system determines, based on the offset metric for each selected block family, whether the selected block families together satisfy a combination threshold criterion. In some embodiments, the combination threshold criterion specifies the maximum difference between the offset metrics associated with the selected block families. If the combination threshold is satisfied (i.e., if the difference between the block family offset metrics is less than or equal to the maximum difference value specified by the criterion), the system combines the selected block families into one block family. If the combination threshold criterion is not satisfied, the system selects other block families to measure against the combination threshold criterion. In some embodiments, the other block families include a number of the previously selected block families. Further details with regards to the operations of the block family manager component 113 are described below.

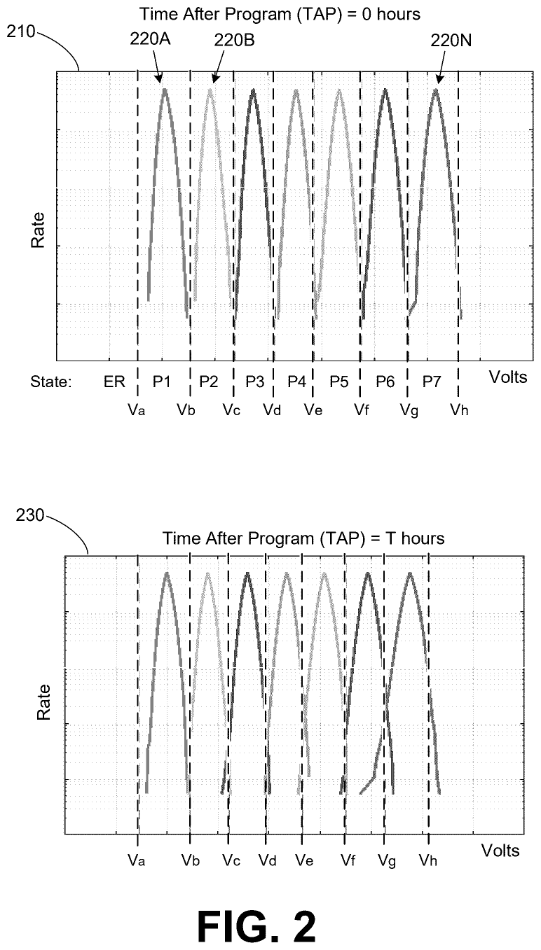

FIG. 2 schematically illustrates the temporal voltage shift caused by the slow charge loss exhibited by triple-level memory cells, in accordance with some embodiments of the present disclosure. While the illustrative example of FIG. 2 utilizes triple-level cells, the same observations can be made and, accordingly, the same remedial measures are applicable to single level cells and multi-level cells, as well as any other fractional or whole number of bits per cell (e.g., 3.5 bits per cell, etc.), in order to compensate for the slow charge loss.

As noted above, a memory cell can be programmed (written to) by applying a certain voltage to the memory cell, which results in an electric charge being held by the memory cell, thus allowing modulation of the voltage distributions produced by the memory cell. Precisely controlling the amount of the electric charge stored by the memory cell allows to establish multiple threshold voltage levels corresponding to different logical levels, thus effectively allowing a single memory cell to store multiple bits of information: a memory cell operated with 2n different threshold voltage levels is capable of storing n bits of information.

In FIG. 2, each graph 220A-220N shows a voltage distribution produced by memory cells programmed by a respective write level (which can be assumed to be at the midpoint of the distribution) to encode a corresponding logical level (“000” through “111” in case of a TLC). In order to distinguish between neighboring distributions (corresponding to two different logical levels), the threshold voltage levels (shown by dashed vertical lines) are defined, such that any measured voltage that falls below a threshold level is associated with one distribution of the pair of neighboring distributions, while any measured voltage that is greater than or equal to the threshold level is associated with another distribution of the pair of neighboring distributions.

As seen from comparing example charts 210 and 230, which reflect the time periods immediately after programming and a respective number of hours after programming, respectively, the voltage distributions change in time due to the slow charge loss, which results in drifting values of the threshold voltage levels, which are shown by dashed vertical lines. In various embodiments of the present disclosure, the temporal voltage shift is selectively tracked for programmed pages or blocks grouped by block families, and appropriate voltage offsets, which are based on page or block affiliation with a certain block family, are applied to the base read levels in order to perform read operations.

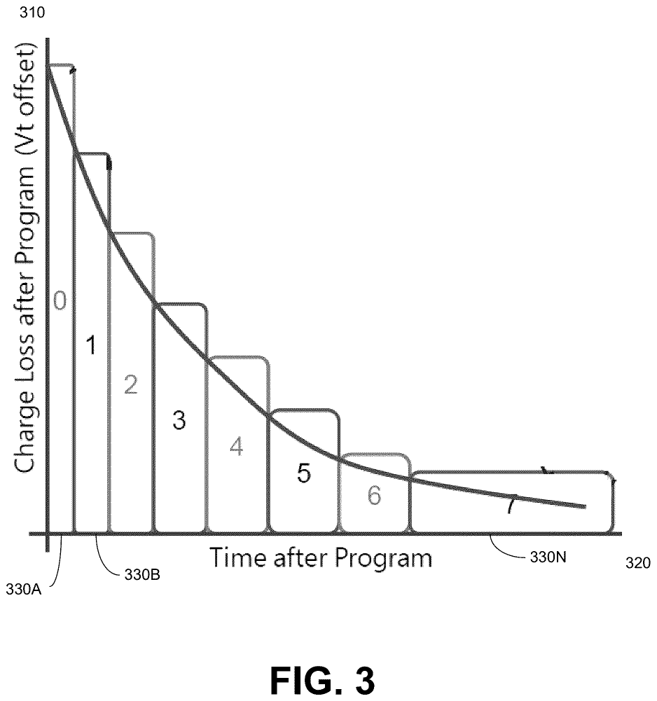

FIG. 3 depicts an example graph illustrating the dependency of the threshold voltage offset on the time after program (i.e., the period of time elapsed since the page had been programmed, in accordance with some embodiments of the present disclosure. As schematically illustrated by FIG. 3, block families of the memory device are grouped into bins 330A-330N, such that each block family includes one or more pages or blocks that have been programmed within a specified time window and a specified temperature window. As noted herein above, since the time elapsed after programming and temperature are the main factors affecting the temporal voltage shift, all pages, blocks, and/or partitions within a single block family 310 are presumed to exhibit similar distributions of threshold voltages in memory cells, and thus would require the same voltage changes for read operations.

Block families can be created asynchronously with respect to page programming events. In an illustrative example, the memory sub-system controller 115 of FIG. 1 can create a new block family whenever a specified period of time (e.g., a predetermined number of minutes) has elapsed since creation of the last block family or whenever the reference temperature of memory cells, which is updated at specified time intervals, has changed by more than a specified threshold value since creation of the current block family.

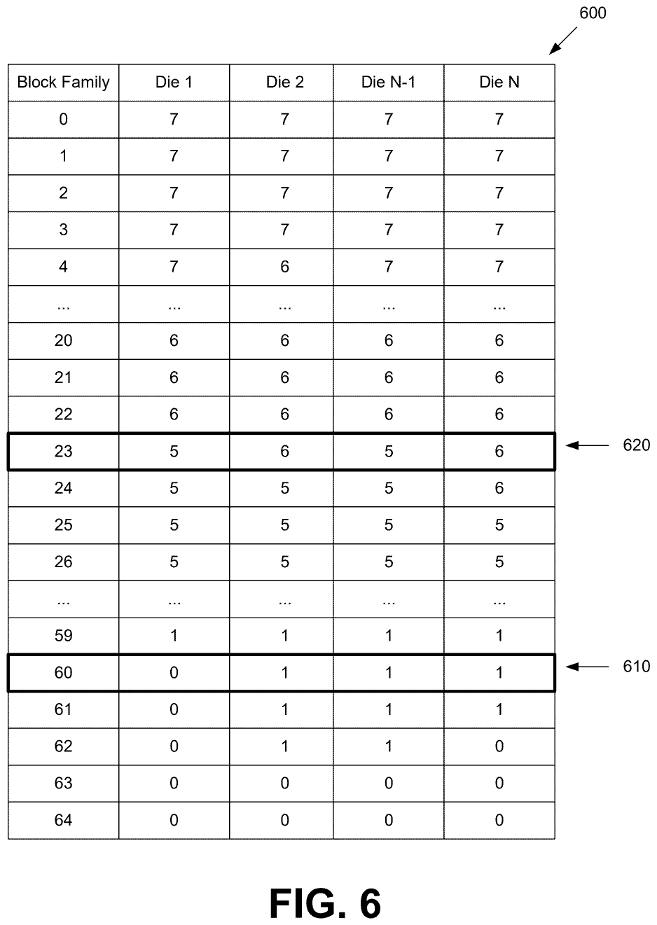

A newly created block family can be associated with a particular bin (e.g., bin 0, bin 1, etc.). Then, the memory sub-system controller can periodically perform a calibration process in order to associate each die of every block family with one of the predefined voltage bins (bins 0-7 in the illustrative example of FIG. 3), which is in turn associated with the voltage offset to be applied for read operations. The associations of blocks with block families and block families and dies with voltage bins can be stored in respective metadata tables maintained by the memory sub-system controller, such as the block family table 600 described with respect to FIG. 6 below.

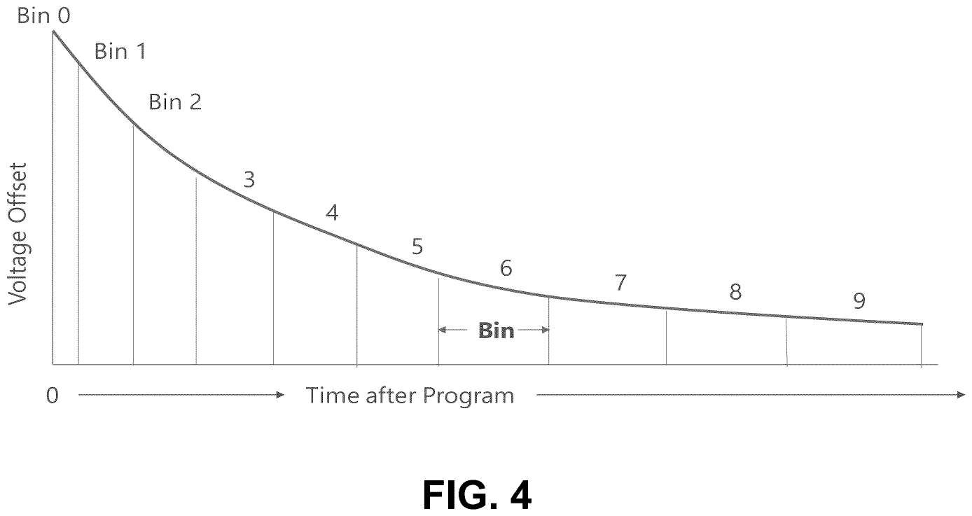

FIG. 4 schematically illustrates a set of predefined threshold voltage offset bins (referred to as voltage bins herein), in accordance with embodiments of the present disclosure. As schematically illustrated by FIG. 4, the threshold voltage offset graph can be subdivided into multiple voltage bins, such that each voltage bin corresponds to a predetermined range of threshold voltage offsets. While the illustrative example of FIG. 4 defines ten voltage bins, in other implementations, various other numbers of voltage bins can be employed (e.g., 64 bins).

The memory sub-system controller can associate each die of every block family with a voltage bin, based on a periodically performed calibration process. The calibration process defines a set of threshold voltage offsets to be applied to the base voltage read level in order to perform read operations. The calibration process involves performing, with respect to a specified number of randomly selected pages or blocks within the block family that is being calibrated, read operations utilizing different threshold voltage offsets, and choosing the threshold voltage offset that minimizes the error rate (e.g., a bit error rate) of the read operation. Further details are provided below.

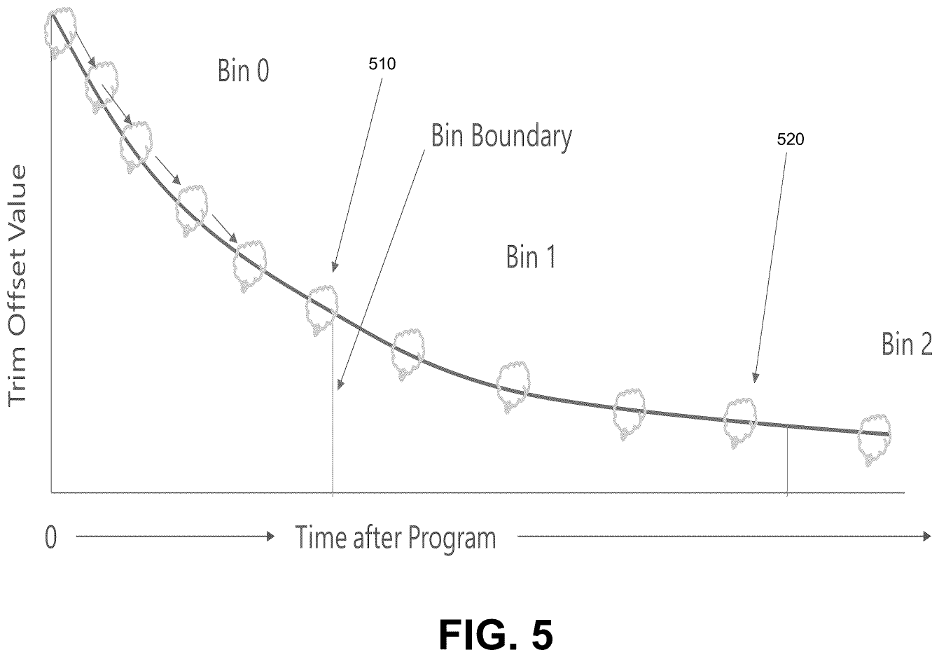

FIG. 5 schematically illustrates selecting block families associated with a voltage offset bin for calibration and combination operations, in accordance with embodiments of the present disclosure. Due to slow charge loss, the oldest block families in a voltage bin migrate to the next voltage bin before any other block families of the current bin. As such, the memory sub-system controller can limit calibration and combination operations to the oldest block families in a bin (e.g., block family 510 in bin 0 and block family 520 in bin 1). In some embodiments, the memory sub-system controller can identify the oldest block family in a voltage bin based on a bin boundary for the bin. A bin boundary can represent a boundary between two adjacent block families that are each associated with a different bin. As described previously, the memory sub-system controller maintains a respective metadata table, which is configured to store associates of block families and dies with voltage offset bins.

FIG. 6 illustrates an example block family table 600 (e.g., a metadata table) maintained by the memory sub-system controller. Block family table 600 can be stored in memory of the memory sub-system (e.g., at memory device 130, 140, local memory 119, etc.) and can be referenced by the memory sub-system controller to determine the voltage bin associated with a particular block family. Block family table 600 is indexed by the block family number, such that each record of the block family table 600 specifies, for the block family referenced by the index of record, a set of voltage bins associated with respective dies of the block family. In other words, each record of the block family table 600 includes a vector, each element of which specifies the voltage bin associated with the die referenced by the index of the vector element (referred to as a bin pointer). The memory sub-system controller determines the voltage bin associated with a particular block family based on the bin pointer having the lowest value included in the vector for the block family. In an illustrative example, the lowest bin pointer value of the vector for block family 60 is associated with voltage bin 0 (i.e., for die 1). Therefore, the memory sub-system controller associates block family 60 with voltage bin 0. In response to receiving a request to read data included in block family 60, the memory sub-system controller uses the threshold voltage associated with voltage bin 0, regardless of whether the requested data is stored at die 1 or die 2 through N.

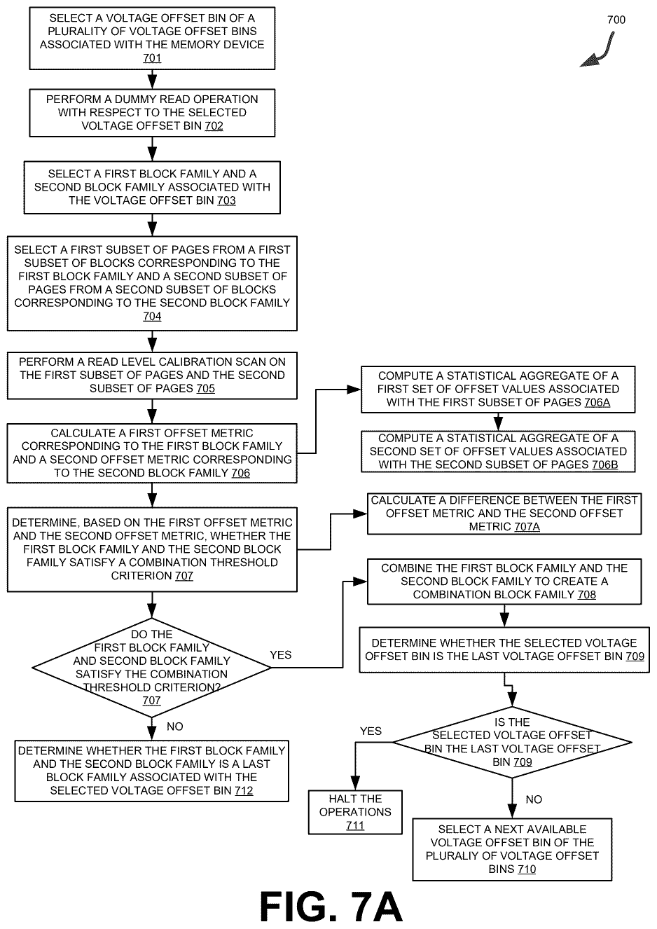

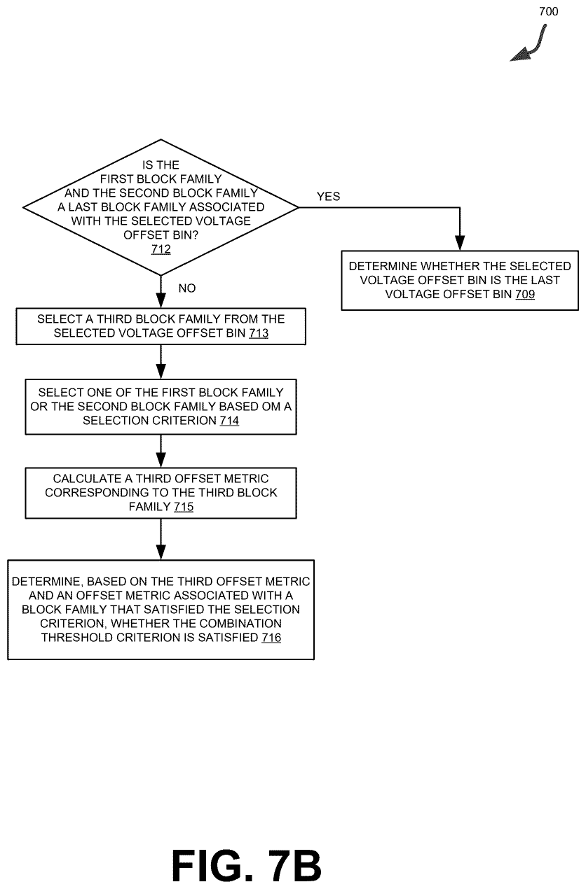

FIG. 7A and FIG. 7B are flow diagrams of an example method 700 for performing block family calibration and combination operations, in accordance with some embodiments of the present disclosure. The method 700 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 700 is performed by the block family manager component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Referring to FIG. 7A at operation 701, the processing logic (e.g., block family manager component 113) selects a voltage offset bin of a plurality of voltage offset bins associated with the memory device.

At operation 702, the processing logic performs a dummy read operation with respect to the selected voltage offset bin. In memory devices, a dummy read operation is a technique used to stabilize and prepare memory cells for accurate data access. During a dummy read, the memory sub-system controller activates a specific row of memory cells, allowing the sense amplifiers to detect and amplify the small voltage differences representing stored data. This operation refreshes the charge in the capacitors, thereby stabilizing the data and ensuring that subsequent read or write operations access accurate information.

At operation 703, the processing logic selects a first block family and a second block family associated with the voltage offset bin. In some embodiments, the first block family is the least recently created block family associated with the selected voltage offset bin. In some embodiments, the second block family is a block family that is logically adjacent to the first block family.

At operation 704, the processing logic selects a first subset of pages from a first subset of blocks associated with the first block family and a second subset of pages from a second subset of blocks associated with the second block family. In some embodiments, the first subset of pages and the second subset of pages is three and the first subset of blocks and the second subset of blocks is three. In this embodiment, there would be 18 pages, three for each block, and nine for each block family.

At operation 705, the processing logic performs a read level calibration scan on the first subset of pages and the second subset of pages.

In some embodiments, as part of the read level calibration scan, the processing logic conducts a series of read operations using different voltage offsets that correspond to the various voltage bins (for example, bins 0-7). Each read operation is performed by applying a particular threshold voltage offset, and the device determines a bit error rate for each operation—this rate represents the number of bits that have been altered due to an error during the read. The device identifies the read operation that resulted in the lowest bit error rate. It determines the threshold voltage offset (and hence the corresponding voltage bin) used during that optimal read operation. Upon identifying the read operation that resulted in the lowest bit error rate, the block family manager 113 updates the metadata for the block family (e.g., the block family table 600) to reflect the determined voltage bin.

In some embodiments, the read level calibration scan is a vectorized read level calibration (vRLC) scan. As part of the vRLC scan, in some embodiments, the processing logic samples a set of readings from a memory page using different threshold voltage offsets relative to a base read level. One reading is taken at the base level (yielding a center result), a second is taken at a lower voltage (the left result, using a left offset), and a third is taken at a higher voltage (the right result, using a right offset). These offsets are predetermined values, measured in units (or “ticks”) such as 10 millivolts (mV) or 20 m V, and can be either symmetrical or asymmetrical.

Using the sampling, the media manager generates two vectors—one for the left and one for the right—by comparing the center result with the left and right results, respectively. Each vector comprises two components: one that captures characteristics of the error distribution (for example, width, depth, slope, or symmetry) and another that reflects the magnitude of the applied offset. The magnitudes of these vectors are then calculated using the Euclidean formula.

The current read level is considered optimal if these vectors satisfy a predetermined relationship, such as having equal magnitudes within a certain limit or exhibiting phase angles that are nearly equal and opposite. If this calibration criterion is not met, the media manager estimates an offset—both in magnitude and direction—to adjust the current read level. This adjustment process is iterative: after applying the estimated offset, new readings are taken to recalculate the vectors until the calibration condition is satisfied.

Once calibration is complete, additional read operations are performed to obtain final measurements. The valley margin is determined by the difference between the final left and right readings, the valley floor is defined by the final center reading, and the valley shift is derived from the change between the initial and final center readings. Alternatively, a mathematical model such as a curve-fit or an asymmetric model can be applied to the multiple read values to solve for the valley metrics. These metrics are then compared to predetermined thresholds to decide whether to trigger further media management operations, with threshold values potentially adjusted based on specific die or memory group parameters. The block family manager 113 updates the metadata table for the block family (e.g., the block family table 600) to reflect the determined voltage bin based on the metrics.

At operation 706, the processing logic calculates a first offset metric corresponding to the first block family and a second offset metric corresponding to the second block family. In some embodiments, at operation 706A, the processing logic calculates the first offset metric corresponding to the first block family at least by computing a statistical aggregate of a first set of offset values associated with the first subset of pages. For example, in an embodiment where the processing logic selects three pages each from three blocks for the first subset of pages and the offset values associated with each page are −1 mV, −2 mV, −3 mV, −3 mV, −3 mV, −3 mV, −3 mV, −4 mV, −5 mV, the calculated first offset metric is −3 mV. Similarly, in some embodiments, at operation 706B the processing logic calculates the second offset metric corresponding to the second block family by at least computing a statistical aggregate of a second set of offset values associated with the second subset of pages.

At operation 707, the processing logic determines, based on the first offset metric and the second offset metric, whether the first block family and the second block family satisfy a combination threshold criterion. In some embodiments, in determining whether the first block family and the second block family satisfy the combination threshold criterion the processing logic calculates a difference between the first offset metric and the second offset metric (at operation 707A). In some embodiments, the combination threshold criterion specifies a maximum offset difference between the first offset metric and the second offset metric. In an example, a first offset metric of −3 mV and a second offset metric of −6 mV satisfies a combination threshold criterion specifying a maximum offset difference of 3 mV. Meanwhile, in the same scenario, if the maximum offset difference is 4 mV, the first block family and the second block family fail to satisfy the combination threshold criterion.

In some embodiments, the combination threshold criterion is specific to the selected voltage offset bin. For example, in an embodiment with 7 voltage offset bins, voltage offset bins 0-4 can have a combination threshold criterion specifying a maximum offset difference of 7 mV while voltage offset bins 5-7 have a combination threshold criterion specifying a maximum offset difference of 3 mV.

Responsive to determining that the first block family and the second block family satisfy the combination threshold criterion, at operation 708, the processing logic combines the first block family and the second block family to create a combination block family. In some embodiments, combining two block families together can refer to merging the blocks of the first block family into the second block family, then deleting the first block family. In another example, combining two block families can refer to creating a new block family and merging the blocks of each of the two block families (e.g., the first block family and the second block family) into the new block family and then deleting the two block families. In some embodiments, each block family has corresponding metadata such as block family identifiers, bin number, and block index. In combining block families, the processing logic updates the metadata of one of the blocks being combined in accordance with that of another block being combined. For example, updating the block family identifier of one block family to match that of the other.

At operation 709, the processing logic determines whether the selected voltage offset bin is the last voltage offset bin. In some embodiments, the last voltage offset bin is the last unselected voltage offset bin in a cycle of selecting voltage offset bins.

Responsive to determining that the selected voltage offset bin is not the last voltage offset bin, at operation 710, the processing logic selects a next available voltage offset bin of the plurality of voltage offset bins. In some embodiments, the next available voltage offset bin is an unselected voltage offset bin that is logically adjacent to the selected voltage offset bin.

Responsive to determining that the selected voltage offset bin is the last voltage offset bin, at operation 711, the processing logic halts calibration and combination operations.

Responsive to determining (at operation 707) that the first block family and the second block family fail to satisfy the combination threshold criterion, at operation 712, the processing logic determines whether the first block family or the second block family is a last block family associated with the selected voltage offset bin. In some embodiments, the last block family is the last unselected block family in a cycle of selecting block families.

Referring to FIG. 7B, responsive to determining that the first block family or the second block family is the last block family associated with the selected voltage offset bin, the processing logic performs operation 709.

Responsive to determining that the first block family or the second block family is not the last block family associated with the selected voltage offset bin, at operation 713, the processing logic selects a third block family from the selected voltage offset bin. In some embodiments, the third block family is an unselected block family logically adjacent to the first block family or the second block family.

At operation 714, the processing logic selects one of the first block family or the second block family based on a selection criterion. In some embodiments, the selection criterion is a lowest offset metric between the first block family and the second block family. For instance, in an example implementation where a first block family has a first offset metric of −3 mV and a second block family has a second offset metric of −6 mV, the processing logic selects the first block family as it has the lowest offset metric (e.g., the closest to zero) between the first block family and the second block family.

At operation 715, the processing logic calculates a third offset metric corresponding to the third block family. In some embodiments, the calculation is performed just as it is performed at operations 706, 706A, and 706B.

At operation 716, the processing logic determines, based on the third offset metric and an offset metric associated with the block family that satisfied the selection criterion (ex. the first block family or the second block family), whether the combination threshold criterion is satisfied. In some embodiments, determining whether the combination threshold criterion is satisfied is performed just as in operations 707 and 707A.

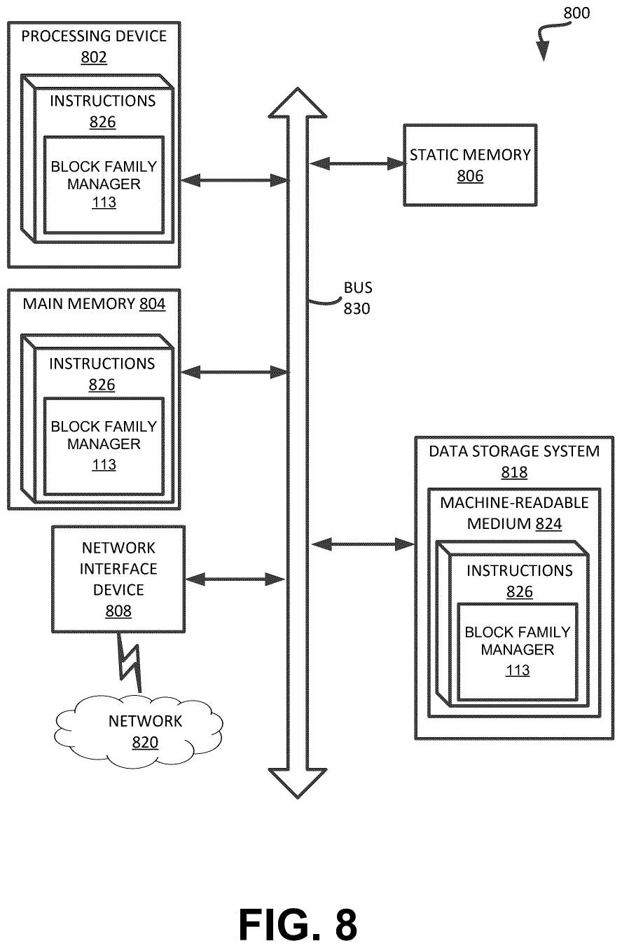

FIG. 8 illustrates an example machine of a computer system 800 within which a set of instructions, for causing the machine to perform any one or more of the methodologies discussed herein, can be executed. In some embodiments, the computer system 800 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the block family manager component 113 of FIG. 1). In alternative embodiments, the machine can be connected (e.g., networked) to other machines in a LAN, an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM) or RDRAM, etc.), a static memory 806 (e.g., flash memory, static random access memory (SRAM), etc.), and a data storage system 818, which communicate with each other via a bus 830.

Processing device 802 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 can also be one or more special-purpose processing devices such as an application specific integrated circuit (ASIC), a field programmable gate array (FPGA), a digital signal processor (DSP), network processor, or the like. The processing device 802 is configured to execute instructions 826 for performing the operations and steps discussed herein. The computer system 800 can further include a network interface device 808 to communicate over the network 820.

The data storage system 818 can include a machine-readable storage medium 824 (also known as a computer-readable medium) on which is stored one or more sets of instructions 826 or software embodying any one or more of the methodologies or functions described herein. The instructions 826 can also reside, completely or at least partially, within the main memory 804 and/or within the processing device 802 during execution thereof by the computer system 800, the main memory 804 and the processing device 802 also constituting machine-readable storage media. The machine-readable storage medium 824, data storage system 818, and/or main memory 804 can correspond to the memory sub-system 110 of FIG. 1.

In one embodiment, the instructions 826 include instructions to implement functionality corresponding to a block family manager component (e.g., the block family manager component 113 of FIG. 1). While the machine-readable storage medium 824 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
selecting a voltage offset bin of a plurality of voltage offset bins associated with the memory device;
selecting a first block family and a second block family associated with the voltage offset bin;
selecting a first subset of pages from a first subset of blocks associated with the first block family and a second subset of pages from a second subset of blocks associated with the second block family;
performing a read level calibration scan on the first subset of pages and the second subset of pages;
calculating a first offset metric corresponding to the first block family and a second offset metric corresponding to the second block family;
determining, based on the first offset metric and the second offset metric, whether the first block family and the second block family satisfy a combination threshold criterion; and
responsive to determining that the first block family and the second block family satisfy the combination threshold criterion, combining the first block family and the second block family to create a combination block family.

2. The system of claim 1, wherein the first block family is the least recently created block family associated with the selected voltage offset bin.

3. The system of claim 1, wherein calculating the first offset metric corresponding to the first block family comprises computing a statistical aggregate of a first set of offset values associated with the first subset of pages.

4. The system of claim 1, wherein determining whether the first block family and the second block family satisfy the combination threshold criterion comprises:
calculating a difference between the first offset metric and the second offset metric.

5. The system of claim 4, wherein the combination threshold criterion specifies a maximum offset difference between the first offset metric and the second offset metric.

6. The system of claim 5, wherein the combination threshold criterion is specific to the selected voltage offset bin.

7. The system of claim 1, wherein the operations further comprise:
responsive to determining that the first block family and the second block family fail to satisfy the combination threshold criterion:
determining whether the first block family or the second block family is a last block family associated with the selected voltage offset bin;
responsive to determining that neither the first block family nor the second block family is the last block family associated with the selected voltage offset bin, selecting a third block family from the selected voltage offset bin;
selecting one of the first block family or the second block family based on a selection criterion;
calculating a third offset metric corresponding to the third block family; and
determining, based on the third offset metric and an offset metric associated with a block family that satisfied the selection criterion, whether the combination threshold criterion is satisfied.

8. The system of claim 7, wherein the selection criterion is a lowest offset metric between the first block family and the second block family.

9. The system of claim 1, wherein the operations further comprise:
determining whether the selected voltage offset bin is the last voltage offset bin; and
responsive to determining that the selected voltage offset bin is not the last voltage offset bin, selecting a next available voltage offset bin of the plurality of voltage offset bins.

10. The system of claim 1, wherein the operations further comprise:
performing a dummy read operation with respect to the selected voltage offset bin.

11. The system of claim 1, wherein the read level calibration scan is a vectorized read level calibration scan (vRLC).

12. A method comprising:
selecting, by a processing device, a voltage offset bin of a plurality of voltage offset bins associated with a memory device;
selecting a first block family and a second block family associated with the voltage offset bin;
selecting a first subset of pages from a first subset of blocks associated with the first block family and a second subset of pages from a second subset of blocks associated with the second block family;
performing a read level calibration scan on the first subset of pages and the second subset of pages;
calculating a first offset metric corresponding to the first block family and a second offset metric corresponding to the second block family;
determining, based on the first offset metric and the second offset metric, whether the first block family and the second block family satisfy a combination threshold criterion; and
responsive to determining that the first block family and the second block family satisfy the combination threshold criterion, combining the first block family and the second block family to create a combination block family.

13. The method of claim 12, wherein calculating the first offset metric corresponding to the first block family comprises computing a statistical aggregate of a first set of offset values associated with the first subset of pages.

14. The method of claim 12, wherein determining whether the first block family and the second block family satisfy the combination threshold criterion comprises:
calculating a difference between the first offset metric and the second offset metric.

15. The method of claim 12, further comprising:
responsive to determining that the first block family and the second block family fail to satisfy the combination threshold criterion:
determining whether the first block family or the second block family is a last block family associated with the selected voltage offset bin;
responsive to determining that neither the first block family nor the second block family is the last block family associated with the selected voltage offset bin, selecting a third block family from the selected voltage offset bin;
selecting one of the first block family or the second block family based on a selection criterion;
calculating a third offset metric corresponding to the third block family; and
determining, based on the third offset metric and an offset metric associated with a block family that satisfied the selection criterion, whether the combination threshold criterion is satisfied.

16. The method of claim 12, further comprising:
determining whether the selected voltage offset bin is the last voltage offset bin; and
responsive to determining that the selected voltage offset bin is not the last voltage offset bin, selecting a next available voltage offset bin of the plurality of voltage offset bins.

17. A non-transitory computer-readable storage medium comprising instructions that, when executed by a processing device, cause the processing device to perform operations comprising:
selecting a voltage offset bin of a plurality of voltage offset bins associated with a memory device;
selecting a first block family and a second block family associated with the voltage offset bin;
selecting a first subset of pages from a first subset of blocks associated with the first block family and a second subset of pages from a second subset of blocks associated with the second block family;
performing a read level calibration scan on the first subset of pages and the second subset of pages;
calculating a first offset metric corresponding to the first block family and a second offset metric corresponding to the second block family;
determining, based on the first offset metric and the second offset metric, whether the first block family and the second block family satisfy a combination threshold criterion; and
responsive to determining that the first block family and the second block family satisfy the combination threshold criterion, combining the first block family and the second block family to create a combination block family.

18. The non-transitory computer-readable storage medium of claim 17, wherein determining whether the first block family and the second block family satisfy the combination threshold criterion comprises:
calculating a difference between the first offset metric and the second offset metric.

19. The non-transitory computer-readable storage medium of claim 17, wherein the operations further comprise:
responsive to determining that the first block family and the second block family fail to satisfy the combination threshold criterion:
determining whether the first block family or the second block family is a last block family associated with the selected voltage offset bin;
responsive to determining that neither the first block family nor the second block family is the last block family associated with the selected voltage offset bin, selecting a third block family from the selected voltage offset bin;
selecting one of the first block family or the second block family based on a selection criterion;
calculating a third offset metric corresponding to the third block family; and
determining, based on the third offset metric and an offset metric associated with a block family that satisfied the selection criterion, whether the combination threshold criterion is satisfied.

20. The non-transitory computer-readable storage medium of claim 17, wherein the operations further comprise:
determining whether the selected voltage offset bin is the last voltage offset bin; and
responsive to determining that the selected voltage offset bin is not the last voltage offset bin, selecting a next available voltage offset bin of the plurality of voltage offset bins.
